(19) United States
(12) Patent Application Publication
(10) Pub. No.: US 2009/0065830 A1
(43) Pub. Date: Mar. 12, 2009

(54) Image Sensor and a Method for Manufacturing the Same

(76) Inventor: Woo Seok HYUN, Seo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/205,155

(22) Filed: Sep. 5, 2008

(30) Foreign Application Priority Data
Sep. 7, 2007 (KR) 10-2007-0090862

(51) Int. Cl. H01L 31/112; H01L 21/265

(52) U.S. Cl. 257/292; 438/73; 257/E31.079; 257/E21.334

(57) ABSTRACT

An image sensor and manufacturing method thereof are provided. A semiconductor substrate can include a center region and an edge region, each with a gate. A first impurity region and a second impurity region can be provided in the semiconductor substrate to a first side of each gate. A floating diffusion region can be provided to a second side of teach gate. A third impurity region can be provided in the semiconductor substrate to the first side of the gate in the edge region.

### CROSS-REFERENCE TO RELATED APPLICATION

The present application claims the benefit under 35 U.S.C. §119 of Korean Patent Application No. 10-2007-0090862, filed Sep. 7, 2007, which is hereby incorporated by reference in its entirety.

### BACKGROUND

An image sensor is a semiconductor device that converts an optical image into an electrical signal. An image sensor typically includes an optical sensing region for sensing light and a logic circuit region for processing the sensed light into an electrical signal to make it data.

In particular, a complementary metal oxide semiconductor (CMOS) image sensor uses a switching scheme including photodiodes and MOS transistors in unit pixels and sequentially detects outputs therefrom.

A CMOS image sensor collects light in a pixel array, typically configured of several tens to several millions of unit pixels, and converts it into an electrical signal. Also, the pixel array generally includes a microlens for collecting light for each unit pixel and a main lens covering the entire pixel array.

Light incident through the main lens is collected into a unit pixel through each microlens. In general, there may be a difference in light-collecting efficiency between a center region and an edge region of the pixel array.

That is, incident light is approximately perpendicular on the center region of the pixel array so that there is little image distortion. However, incident light on the edge region of the pixel array typically has a tilt angle so that a clear image is difficult to obtain.

### BRIEF SUMMARY

Embodiments of the present invention provide image sensors and manufacturing methods thereof capable of increasing productivity of optical charge in an edge region of a pixel array.

In an embodiment, an image sensor can comprise: a semiconductor substrate comprising a center region and an edge region; a center gate disposed in the center region; an edge gate disposed in the edge region; a first center impurity region disposed in the semiconductor substrate in the center region to a first side of the center gate; a first edge impurity region disposed in the semiconductor substrate in the edge region to a first side of the edge gate; a second center impurity region disposed in the semiconductor substrate in the center region to the first side of the center gate; a third edge impurity region disposed in the semiconductor substrate in the edge region to the first side of the edge gate; a second edge impurity region disposed in the semiconductor substrate in the edge region on the third edge impurity region; a center floating diffusion region disposed on the semiconductor substrate in the center region to a second side of the center gate opposite from the first side of the center gate; and an edge floating diffusion region disposed on the semiconductor substrate in the edge region to a second side of the edge gate opposite from the first side of the edge gate.

In another embodiment, a method for manufacturing an image sensor can comprise: forming a center gate on a center region of a semiconductor substrate; forming an edge gate on an edge region of a semiconductor substrate; forming a first center impurity region in the semiconductor substrate in the center region to a first side of the center gate; forming a first edge impurity region in the semiconductor substrate in the edge region to a first side of the edge gate; forming a third edge impurity region in the semiconductor substrate in the edge region to the first side of the edge gate; forming a second center impurity region in the semiconductor substrate in the center region to the first side of the center gate; forming a second edge impurity region in the semiconductor substrate in the edge region to the first side of the edge gate; forming a center floating diffusion region on the semiconductor substrate in the center region to a second side of the center gate opposite from the first side of the center gate; and forming an edge floating diffusion region on the semiconductor substrate in the edge region to a second side of the edge gate opposite from the first side of the edge gate;

### BRIEF DESCRIPTION OF THE DRAWINGS

FIGS. 1 to 6 are cross-sectional views showing a method for manufacturing an image sensor according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Image sensors and manufacturing methods thereof according to embodiments of the present invention will be described in detail with reference to the accompanying drawings.

FIG. 6 is a cross-sectional view showing an image sensor according to an embodiment of the present invention.

Referring to FIG. 6, channel areas 110 and 210 can be disposed in a center region A and an edge region B of a semiconductor substrate 10. Gates 120 and 220 can be disposed on at least a portion of the channel areas 110 and 210, respectively. The gates 120 and 220, can be, for example, gates of a transfer transistor.

The semiconductor substrate 10 can be any suitable substrate known in the art. For example, the semiconductor substrate 10 can be a high-concentration p-type substrate (p++). In an embodiment, the semiconductor substrate 10 can include a low concentration p-Epi region formed through an epitaxial process.

The semiconductor substrate 10 can include the center region A and the edge region B. The center region of the semiconductor substrate 10 can be a region where light is vertically incident (such that incident light is approximately perpendicular to the semiconductor substrate 10), and the edge region B can be a region where light is incident with a tilt angle. That is, the edge region B can be located around the center region A on a chip.

A photodiode can be disposed to a side of the gate 120 of the center region A, and a floating diffusion region 170 can be arranged to the other side of the gate 120.

The photodiode of the center region A can include a first impurity region 130 and a second impurity region 160. In an embodiment, the first impurity region 130 can be an n-type impurity region, and the second impurity region 160 can be a p-type impurity region.

In a particular embodiment, the first impurity region 130 can be disposed in the semiconductor substrate 10 of the center region A, and the second impurity region 160 can be arranged on the first impurity region 130 near the surface of the semiconductor substrate 10.

In addition, a photodiode can be disposed to a side of the gate 220 of the edge region B, and a floating diffusion region 270 can be arranged to the other side of the gate 220.

The photodiode of the edge region B can include a first impurity region 230, a third impurity region 240, and a second impurity region 260. In an embodiment, the first impurity region 230 and the third impurity region 240 can be n-type impurity regions, and the second impurity region 260 can be a p-type impurity region.

In certain embodiments, the third impurity region 240 can be provided within the first impurity region 230 in the semiconductor substrate 10 to a side of the gate 220 of the edge region B. According to embodiments, the n-type impurity region for the photodiode of the edge region B can have a higher impurity concentration than the n-type impurity region for the photodiode of the center region A. The photodiode of the edge region B can also include a second impurity region 260 on the third impurity region 240 near the surface of the semiconductor substrate 10 of the edge region B.

A skilled artisan will appreciate that, according to an embodiment of the present invention, the concentration of the n-type impurity region of the photodiode in the edge region B can be higher than that of the photodiode in the center region A. That is, the photodiode of the center region A can be formed with a first impurity region 230 through one n-type impurity implantation, and the photodiode of the edge region B can be formed with a first impurity region 230 and a third impurity region 240 through two n-type impurity implantations.

Since the impurity concentration of the photodiode in the edge region B can be higher than that of photodiode of the center region A the shading characteristics of the edge region B can be enhanced.

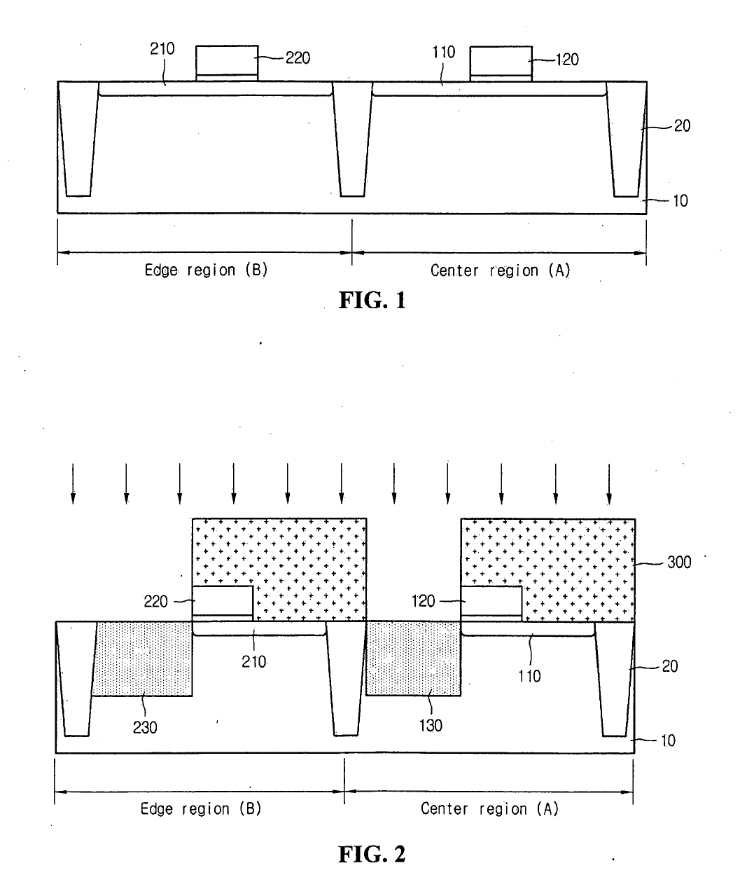

FIGS. 1 to 6 are cross-sectional views showing a method for manufacturing an image sensor according to an embodiment of the present invention.

Referring to FIG. 1, gates 120 and 220 can be formed on a center region A and an edge region B of a semiconductor substrate 10.

The semiconductor substrate 10 can be any suitable type of substrate known in the art. For example, the semiconductor substrate 10 can be a high-concentration p-type substrate (p++). In an embodiment, a low-concentration p-Epi region can be formed on the semiconductor substrate 10 by performing an epitaxial process on the semiconductor substrate 10.

A plurality of device isolating layers 20 defining an active region and a field region can be formed on the semiconductor substrate 10.

The semiconductor substrate 10 can include the center region A and the edge region B. The center region of the semiconductor substrate 10 can be a region where light is vertically incident (such that incident light is approximately perpendicular to the semiconductor substrate 10), and the edge region B can be a region where light is incident with a tilt angle. That is, the edge region B can be located around the center region A on a chip.

Channel areas 110 and 210 can be formed on the center region A and the edge region B. The channel areas 110 and 210 can help control threshold voltage and moving charges generated in a photodiode.

The gates 120 and 220 can be gates of, for example, a transfer transistor. The gates 120 and 220 can be formed through any suitable process known in the art. In an embodiment the gates 120 and 220 can be formed by depositing a gate insulating layer and a gate conductive layer and performing a patterning process on them.

Referring to FIG. 2, first impurity regions 130 and 230 for a photodiode can be formed to a side of the gates 120 and 220 in the center region A and the edge region B.

In an embodiment, in order to form the first impurity regions 130 and 230, a first photoresist pattern 300 can be formed on the semiconductor substrate 10 covering the gates 120 and 220 and a side of the gates 120 and 220 and exposing the other side thereof. Impurity ions can be implanted using the first photoresist pattern 300 as an ion implantation mask, thereby forming the first impurity regions 130 and 230 to a side of the gates 120 and 220. The impurity ions can be, for example, n-type impurity ions.

In an embodiment, forming the first impurity regions 130 and 230 can include implanting arsenic (As) ions at a dose of from about 2.6×10¹² atoms/cm² to about 3.0×10¹² atoms/cm² at an implantation energy of from about 180 keV to about 220 keV.

Then, the first photoresist pattern 300 can be removed. The first photoresist pattern 300 can be removed, for example, by performing an ashing process.

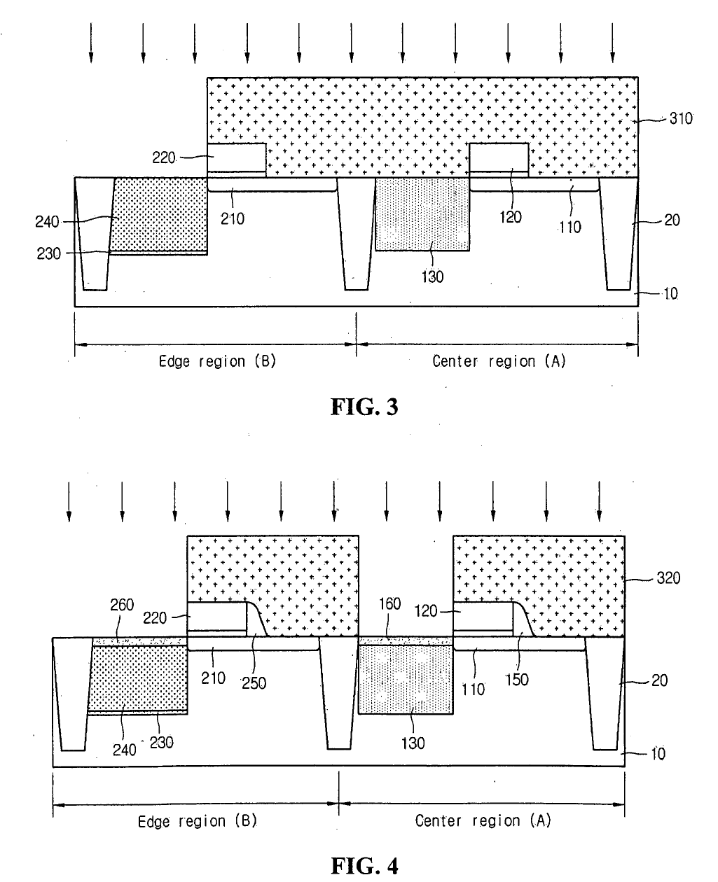

Referring to FIG. 3, a third impurity region 240 for a photodiode can be formed to a side of the gate 220 of the edge region B. The third impurity region 240 can be formed to overlap with the first impurity region 230 of the edge region B.

In an embodiment, in order to form the third impurity region 240, a second photoresist pattern 310 can be formed on the semiconductor substrate 10 exposing the first impurity region 230 of the edge region B and covering the center region A, the gate 220 of the edge region B, and a side of the gate 220 opposite the side where the first impurity region 230 is formed. Impurity ions can be implanted using the second photoresist pattern 310 as an ion implantation mask to form the third impurity region 240 to the side of the gate 220 of the edge region B where the first impurity region 230 was formed. The impurity ions can be, for example, n-type impurity ions.

In an embodiment, forming the third impurity region 240 can include implanting As ions at a dose of from about 0.2×10¹² atoms/cm² to about 0.5×10¹² atoms/cm² at an implantation energy of from about 180 keV to about 220 keV.

The third impurity region 240 region can be formed only on the edge region B so that the edge region B has a higher concentration of the impurity than the center region A. That is, the impurity region to be used for a photodiode of the edge region B can have a higher ion implantation concentration than the impurity region of the center region A by performing the impurity ion implantation twice on the edge region B. Accordingly, the occurrence rate of optical charges in the edge region B can be enhanced.

Then, the second photoresist pattern 310 can be removed. The second photoresist pattern 310 can be removed, for example, by performing an ashing process.

Referring to FIG. 4, spacers 150 and 250 can be formed to a side of each of the gates 120 and 220 opposite the side where the first impurity regions 130 and 230 were formed.

Second impurity regions 160 and 260 for photodiodes can be formed to a side of the gates 120 and 220 of the center region A and the edge region B where the first impurity regions 130 and 230 were formed.

In an embodiment, in order to form the second impurity regions 160 and 260, a third photoresist pattern 320 can be formed on the semiconductor substrate 10 covering the gates 120 and 220 and a side of the gates opposite from where the first impurity regions 130 and 230 were formed and exposing the first impurity region 130 of the center region A and the first impurity region 230 of the edge region B. Impurity ions can be implanted using the third photoresist pattern 320 as an ion implantation mask to form the second impurity regions 160 and 260. The impurity ions can be, for example, p-type impurity ions.

In an embodiment, forming the second impurity regions 160 and 260 can include implanting boron (B) ions at a dose of from about 3.5×10¹¹ atoms/cm² to about 4.5×10¹¹ atoms/cm² at an implantation energy of from about 5 keV to about 10 keV. The second impurity regions 160 and 260 can be formed using lower energy than that of the first impurity regions 130 and 230 and third impurity region 240 so that they can be formed closer to the surface of the substrate at the center region A and the edge region B. In a specific embodiment, the second impurity region 160 of the center region A can be formed in contact with the channel area 110 of the center region A, and the second impurity region 260 of the edge region B can be formed in contact with the channel area 210 of the edge region B.

Then, the third photoresist pattern 320 can be removed. The third photoresist pattern 320 can be removed, for example, by performing an ashing process.

In the center region A, the first impurity region 130 and the second impurity region 160 can form a photodiode in the center region A, and, in the edge region B, the first impurity region 230, the third impurity region 240, and the second impurity region 260 can form a photodiode in the edge region B.

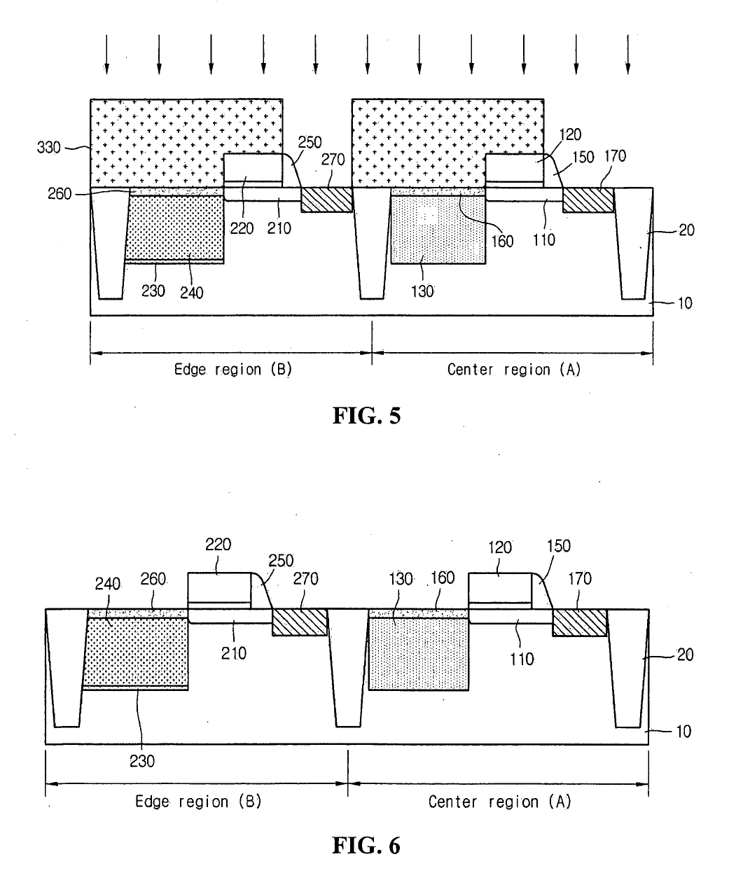

Referring to FIG. 5, floating diffusion regions 170 and 270 can be formed in the center region A and the edge region B to a side of the gates 120 and 220 opposite from where the first impurity regions 130 and 230 were formed. The floating diffusion regions 170 and 270 can be for receiving optical electrons generated in the photodiode.

In an embodiment, in order to form the floating diffusion regions 170 and 270, a fourth photoresist pattern 330 can be formed on the semiconductor substrate 10 covering the gates 120 and 220 and the photodiodes in the center region A and the edge region B and exposing a side of each gate 120 and 220 opposite from where the first impurity regions 130 and 230 were formed. Impurity ions can be implanted using the fourth photoresist pattern 330 as an ion implantation mask to form the floating diffusion regions 170 and 270 to the exposed side of the gates 120 and 220. The impurity ions can be, for example, n-type impurity ions at a high concentration (n+ impurity ions).

Referring again to FIG. 6, the fourth photoresist pattern 330 can be removed. The fourth photoresist pattern 330 can be removed, for example, by performing an ashing process.

In an image sensor according to an embodiment of the present invention, a photodiode in the edge region B can have a higher concentration of n-type impurities than that of a photodiode of the center region A. That is, a photodiode of the center region A can be formed by implanting an n-type impurity once, and a photodiode of the edge region B can be formed by implanting an n-type impurity twice, thereby increasing the n-type impurity concentration of the edge region B.

According to embodiments of the present invention, the impurity concentration of a photodiode in the edge region B can be higher than that of a photodiode in the center region A, making it possible to enhance the occurrence rate of optical charges in the edge region B.

Therefore, the shading characteristics in the edge region B can be improved, thereby enhancing the image characteristics of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate comprising a center region and an edge region;
a center gate disposed in the center region;
an edge gate disposed in the edge region;
a first center impurity region disposed in the semiconductor substrate in the center region to a first side of the center gate;
a first edge impurity region disposed in the semiconductor substrate in the edge region to a first side of the edge gate;
a second center impurity region disposed in the semiconductor substrate in the center region on the first center impurity region;
a third edge impurity region disposed in the semiconductor substrate in the edge region to the first side of the edge gate;
a second edge impurity region disposed in the semiconductor substrate in the edge region on the first edge impurity region;
a center floating diffusion region disposed on the semiconductor substrate in the center region to a second side of the center gate opposite from the first side of the center gate; and
an edge floating diffusion region disposed on the semiconductor substrate in the edge region to a second side of the edge gate opposite from the first side of the edge gate.

2. The image sensor according to claim 1, wherein the first center impurity region, the first edge impurity region, and the third edge impurity region each comprise n-type impurities.

3. The image sensor according to claim 1, wherein the second center impurity region and the second edge impurity region each comprise p-type impurities.

4. The image sensor according to claim 1, wherein the third edge impurity region is disposed within the first edge impurity region.

5. The image sensor according to claim 1, wherein at least a portion of the third edge impurity region overlaps with the first edge impurity region.

6. The image sensor according to claim 1, further comprising:
a center spacer on the semiconductor substrate to the second side of the center gate; and
an edge spacer on the semiconductor substrate to the second side of the edge gate.

7. The image sensor according to claim 1, wherein the first center impurity region and the second center impurity region provide a center photodiode, and wherein the first edge impurity region, the third edge impurity region, and the second edge impurity region provide an edge photodiode.

8. The image sensor according to claim 7, wherein the first center impurity region, the first edge impurity region, and the third edge impurity region each comprise n-type impurities, and wherein a concentration of n-type impurities in the edge photodiode is higher than a concentration of n-type impurities in the center photodiode.

9. A method for manufacturing an image sensor, comprising:
forming a center gate on a center region of a semiconductor substrate;
forming an edge gate on an edge region of a semiconductor substrate;
forming a first center impurity region in the semiconductor substrate in the center region to a first side of the center gate;
forming a first edge impurity region in the semiconductor substrate in the edge region to a first side of the edge gate;
forming a third edge impurity region in the semiconductor substrate in the edge region to the first side of the edge gate;
forming a second center impurity region in the semiconductor substrate in the center region on the first center impurity region;
forming a second edge impurity region in the semiconductor substrate in the edge region on the first edge impurity region;
forming a center floating diffusion region on the semiconductor substrate in the center region to a second side of the center gate opposite from the first side of the center gate; and
forming an edge floating diffusion region on the semiconductor substrate in the edge region to a second side of the edge gate opposite from the first side of the edge gate.

10. The method according to claim 9, wherein the first center impurity region and the first edge impurity region are formed simultaneously, and wherein forming the first center impurity region and the first edge impurity region comprises:
forming a photoresist pattern exposing the first side of the center gate and the first side of the edge gate; and
performing an ion implantation process on the semiconductor substrate using the photoresist pattern as an ion implantation mask.

11. The method according to claim 10, wherein performing the ion implantation process comprises implanting n-type impurity ions.

12. The method according to claim 9, wherein forming the third edge impurity region comprises:
forming a photoresist pattern exposing the first edge impurity region; and
performing an ion implantation process on the semiconductor substrate using the photoresist pattern as an ion implantation mask.

13. The method according to claim 12, wherein performing the ion implantation process comprises implanting n-type impurity ions.

14. The method according to claim 9, wherein the second center impurity region and the second edge impurity region are formed simultaneously, and wherein forming the second center impurity region and the second edge impurity region comprises:
forming a photoresist pattern exposing the first center impurity region and the third edge impurity region; and
performing an ion implantation process on the semiconductor substrate using the photoresist pattern as an ion implantation mask.

15. The method according to claim 14, wherein performing the ion implantation process comprises implanting p-type impurity ions.

16. The method according to claim 9, wherein the first center impurity region, the first edge impurity region, and the third edge impurity region each comprise n-type impurities.

17. The method according to claim 16, wherein the second center impurity region and the second edge impurity region each comprise p-type impurities.

18. The method according to claim 9, wherein at least a portion of the third edge impurity region overlaps with the first edge impurity region.

19. The method according to claim 9, wherein the first center impurity region and the second center impurity region form a center photodiode, and wherein the first edge impurity region, the third edge impurity region, and the second edge impurity region form an edge photodiode.

20. The method according to claim 9, wherein the first center impurity region, the first edge impurity region, and the third edge impurity region each comprise n-type impurities, and wherein a concentration of n-type impurities in the edge photodiode is higher than a concentration of n-type impurities in the center photodiode.
